(19) United States
(12) Patent Application Publication
(10) Pub. No.: US 2021/0151604 A1
(43) Pub. Date: May 20, 2021

(54) THIN FILM TRANSISTOR

(71) Applicant: Japan Display Inc., Tokyo (JP)

(72) Inventors: Takashi OKADA, Tokyo (JP); Masashi TSUBUKU, Tokyo (JP)

(21) Appl. No.: 17/162,340

(22) Filed: Jan. 29, 2021

Related U.S. Application Data
(63) Continuation of application No. PCT/JP2019/022736, filed on Jun. 7, 2019.

(30) Foreign Application Priority Data
Aug. 8, 2018 (JP) 2018-149160

(51) Int. Cl. H01L 29/786

(52) U.S. Cl. CPC H01L 29/7869

(57) ABSTRACT

A thin film transistor comprising an active layer made of an oxide semiconductor containing at least indium and gallium; an electrode layer partially formed on the active layer; an oxide film insulating layer formed on the active layer and the electrode layer; and a nitride film insulating layer formed on the oxide film insulating layer. The thin film transistor further comprises an oxygen diffusion-inhibiting film partially overlapping with the active layer in a plan view between the oxide film insulating layer and the nitride film insulating layer.

### CROSS-REFERENCE TO RELATED APPLICATION

The present application is a Bypass Continuation of International Application No. PCT/JP2019/022736, filed on Jun. 7, 2019, which claims priority from Japanese Application No. JP2018-149160 filed on Aug. 8, 2018. The contents of these applications are hereby incorporated by reference into this application.

### BACKGROUND

### 1. Field

The present invention relates to a thin film transistor.

### 2. Description of the Related Art

JP2010-135760A describes a single channel inverter circuit having a depletion-type transistor and an enhancement-type transistor. In JP2010-135760A, the enhancement-type transistor includes a gate electrode, a gate insulating layer, a first oxide semiconductor layer, a second oxide semiconductor layer, a source electrode, a drain electrode, and a reduction prevention layer provided on the area between the source electrode and the train electrode in the first oxide semiconductor layer.

### SUMMARY

In a transistor such as TAOS-TFT (Transparent Amorphous Oxide Semiconductor-Thin Film Transistor) using an oxide semiconductor, such as IGO and IGZO containing group 13 elements, as an active layer, only an n-type semiconductor can be generated, and thus so-called CMOS configuration combining a n-type semiconductor and a p-type semiconductor is not available.

As such, in a case where a logic circuit such as an inverter circuit is generated using an oxide semiconductor, the circuit needs to be configured using only a n-type semiconductor. At this time, a high-performance circuit may be generated by changing the threshold voltage between the transistors.

The inverter circuit disclosed in JP2010-135760A is an example of such a circuit. However, in Patent Literature 1, a special process of providing a reduction prevention layer is required to obtain an enhancement-type transistor.

One or more embodiments of the present invention have been conceived in view of the above, and an object thereof is to facilitate a change of a threshold voltage of a transistor including an oxide semiconductor as an active layer.

A thin film transistor comprising an active layer made of an oxide semiconductor containing at least indium and gallium; an electrode layer partially formed on the active layer; an oxide film insulating layer formed on the active layer and the electrode layer; and a nitride film insulating layer formed on the oxide film insulating layer, wherein the thin film transistor further comprises an oxygen diffusion-inhibiting film partially overlapping with the active layer in a plan view between the oxide film insulating layer and the nitride film insulating layer.

### BRIEF DESCRIPTION OF THE DRAWINGS

FIG. 1 is a schematic plan view of a transistor according to an embodiment of the present invention;

FIG. 2 is a diagram for illustrating a cross section taken along the line A-A in FIG. 1;

FIG. 3 is a diagram illustrating a cross section of a connecting portion of FIG. 1;

FIG. 4 is a graph showing measured drain current value with respect to a gate voltage of the transistor in a case where an oxygen diffusion-inhibiting film is not formed;

FIG. 5 is a graph showing measured drain current value with respect to the gate voltage of the transistor in a case where the oxygen diffusion-inhibiting film is formed;

FIG. 6 is a cross-sectional view of another embodiment of the transistor;

FIG. 7 is a cross-sectional view of yet another embodiment of the transistor;

FIG. 8 is a diagram illustrating an example of an electronic circuit using the transistor according to the present embodiment; and

FIG. 9 is a circuit diagram of the electronic circuit.

### DETAILED DESCRIPTION OF THE INVENTION

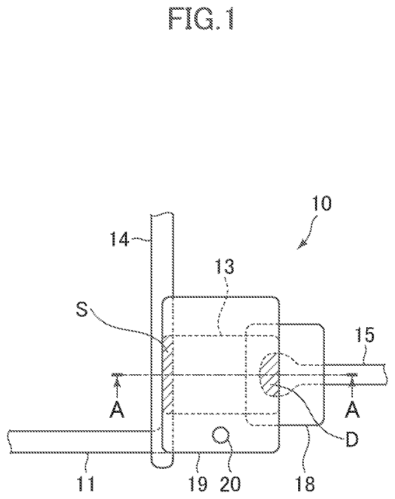

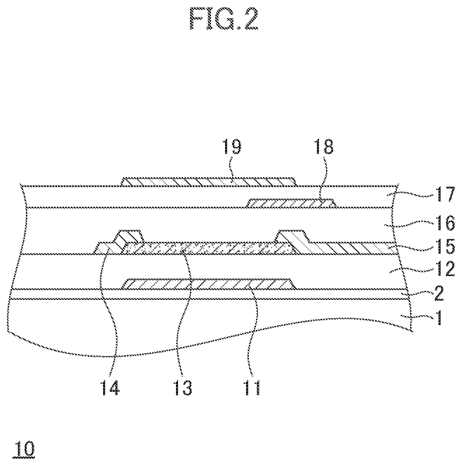

FIG. 1 is a schematic plan view of a transistor 10 according to an embodiment of the present invention, and FIG. 2 is a diagram for illustrating a cross section taken along the line A-A in FIG. 1.

The transistor 10 is a thin film transistor formed on an undercoat layer 2 on a substrate 1 using a photolithographic technique. The substrate 1 is an inorganic or an organic substrate, such as a glass substrate, a quartz substrate, and a resin substrate, and may be rigid or flexible. Further, the undercoat layer 2 is a film that functions as a barrier layer against impurities contained in the substrate 1 or impurities entering from the back side of the substrate 1. In this case, the undercoat layer 2 may be formed of silicon nitride, silicon nitride oxide, aluminum nitride, aluminum nitride oxide, aluminum oxide, which have excellent barrier properties, or a laminated film containing these materials.

A lower gate electrode 11 is formed on the undercoat layer 2. The lower gate electrode layer 11 may use a metal, such as aluminum, titanium, chromium, molybdenum, tantalum, and tungsten, or an alloy containing these metals. The gate electrode of the transistor may use not only the metal materials described above but also a transparent conductive material, such as ITO and IZO. In a case where such a layer is used not only as the gate electrode of the transistor but as a conductive layer for forming surrounding wiring, it is more preferable to use the metal material described above, since low resistance is required. The lower gate electrode 11 may be formed to have a thickness of about 50 nm to 700 nm, preferably 100 nm to 500 nm.

A gate insulating layer 12 is formed on the lower gate electrode 11. The gate insulating layer 12 may be formed of silicon nitride, silicon nitride oxide, silicon oxide, or a laminated film containing these materials. The gate insulating layer 12 may be formed to have a thickness of about 50 nm to 700 nm, preferably about 100 nm to 500 nm.

Further, an oxide semiconductor layer 13 is formed on the gate insulating layer 12 in an area to overlap with the lower gate electrode 11. The oxide semiconductor layer 13 is an active layer of the transistor 10, and a metal oxide containing at least indium and gallium in the group 13 elements. In the present embodiment, the oxide semiconductor layer 13 is a transparent semiconductor made of oxides of indium, gallium, and zinc known as IGZO. The oxide semiconductor layer 13 may contain other elements, such as tin belonging to the group 14 elements, and titanium and zirconium belonging to the group 4 elements. The oxide semiconductor layer 13 may be formed to have a thickness of about 5 nm to 100 nm, preferably 5 nm to 60 nm.

The crystallinity of the oxide semiconductor layer 13 is not particularly limited, and may be any of a single crystal, a polycrystal, and a microcrystal. Alternatively, the oxide semiconductor layer 13 may be amorphous. The characteristics of the oxide semiconductor layer 13 may preferably include few crystal defects such as oxygen deficiency, and a low hydrogen content concentration. This is because hydrogen contained in the oxide semiconductor layer 13 functions as a donor and induces a current leakage of the transistor.

An electrode layer is formed on the oxide semiconductor layer 13 and the gate insulating layer 12 so as to be partially in contact with the oxide semiconductor layer 13. The electrode layer has a shape of the source electrode 14 and the drain electrode 15 by patterning, and the source electrode 14 and the drain electrode 15 disposed at a predetermined distance without being in contact with each other on the oxide semiconductor layer 13. As such, there is a portion that is not covered by the electrode layer on the oxide semiconductor layer 13. Similarly to the lower gate electrode 11, the electrode layer may use a metal such as aluminum, titanium, chromium, molybdenum, tantalum, and tungsten, or an alloy containing these metals. Further, the electrode layer may be a single layer or a multilayer. The source electrode 14 is in contact and electrically connected with the oxide semiconductor layer 13 in an area S, and the drain electrode 15 is in contact and electrically connected with the oxide semiconductor layer 13 in an area D. The electrode layer is formed in contact with the oxide semiconductor layer 13, and thus, the surface of the electrode layer in contact with the oxide semiconductor layer 13 may preferably be formed of a material having ohmic resistive properties at the connection part thereof. The electrode layer may be formed to have a thickness of about 50 nm to 1 μm, preferably 300 nm to 700 nm.

An oxide film insulating layer 16 and a nitride film insulating layer 17 are formed in this order on the oxide semiconductor layer 13 and the electrode layer. The oxide film insulating layer 16 and the nitride film insulating layer 17 function as gate insulating layers with respect to an upper gate electrode 19 to be described later, and may be formed to have a thickness in total about 50 nm to 700 nm, preferably 100 nm to 500 nm, similarly to the thickness of the gate insulating layer 12. In the present embodiment, the oxide film insulating layer 16 is formed of silicon oxide, and the nitride film insulating layer 17 is formed of silicon nitride.

An oxygen diffusion-inhibiting film 18 is formed between the oxide film insulating layer 16 and the nitride film insulating layer 17. In the present embodiment, the oxygen diffusion-inhibiting film 18 is a metal film, and for example, aluminum, titanium, chromium, molybdenum, tantalum, or tungsten, or an alloy containing these metals can be used. The main function of the oxide film insulating layer 16 is to shield the diffusion of oxygen, which is caused by the heating during the manufacturing process of the transistor 10, from the oxide semiconductor layer 13 to the upper portion. As such, the material of the oxygen diffusion-inhibiting film 18 is not limited to a metal if the material is capable of inhibiting such oxygen diffusion. When a metal is used, the oxygen diffusion-inhibiting film 18 may be formed to have a thickness of about 50 nm to 700 nm, preferably 100 nm to 500 nm.

In this embodiment, the oxygen diffusion-inhibiting film 18 is provided so as to overlap with the drain electrode 15 and a part of the oxide semiconductor layer 13 on the drain electrode 15 side. When being formed of metal, the oxygen diffusion-inhibiting film 18 is not connected to any electrode and in an electrically floating state.

An upper gate electrode 19 may be formed on the nitride film insulating layer 17 at a position to overlap with the oxide semiconductor layer 13. Similarly to the lower gate electrode 11, the upper gate electrode 19 may use a metal such as aluminum, titanium, chromium, molybdenum, tantalum, and tungsten, or an alloy containing these materials. The electrode layer may be a single layer or a multilayer, and use a transparent conductive material, such as ITO and IZO. Similarly to the lower gate electrode 11, the upper gate electrode 19 may be formed to have a thickness of about 50 nm to 700 nm, preferably 100 nm to 500 nm.

In a case where the upper gate electrode 19 is formed, the lower gate electrode 11 and the upper gate electrode 19 are electrically connected to each other by a connecting portion 20.

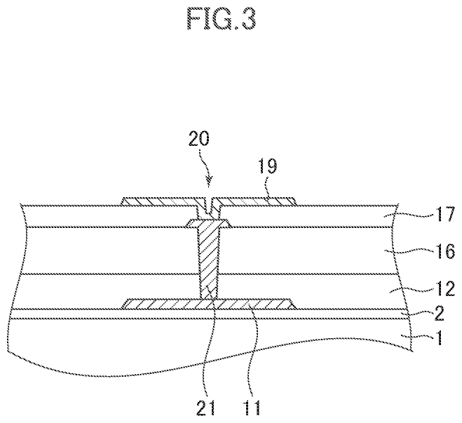

FIG. 3 is a diagram illustrating a cross section of the connecting portion 20 of FIG. 1. The connecting portion 20 has a metal columnar structure 21 connected to the lower gate electrode 11 through the gate insulating film 20 and the oxide film insulating layer 16, and is formed by the upper gate electrode 19 penetrating the nitride film insulating layer 17 to connect to the columnar structure 21.

The columnar structure 21 is a metal layer formed after the oxide film insulating layer 16 is formed, and located in the same layer as the oxygen diffusion-inhibiting film 18. As such, the columnar structure 21 and the oxygen diffusion-inhibiting film 18 can be manufactured in the same process by patterning, and a special process is not additionally needed for forming the oxygen diffusion-inhibiting film 18.

The oxygen diffusion-inhibiting film 18 is electrically floating, and thus its potential is not uniquely determined. As such, the transistor 10 can be switched on and off without affecting the potential applied by the lower gate electrode 11 and the upper gate electrode 19.

The transistor 10 is thus formed on the substrate 1. Depending on the application of the transistor 10, an electric circuit may be formed at the same time of forming the upper gate electrode 19. Alternatively, an insulating layer, such as a flattening layer, may be further provided on the transistor 10 so as to connect the electrical circuit formed thereon and each electrode of the transistor 10 via a through hole. In this manner, any electrical circuit having the transistor 10 is formed.

The transistor 10 shown in this example is a so-called dual gate type transistor having the upper gate electrode 19 and the lower gate electrode 11 respectively above and below the oxide semiconductor layer 13. Alternatively, the transistor 10 may be a so-called staggered or inverted staggered transistor having only one of the lower gate electrode 11 and the upper gate electrode 19.

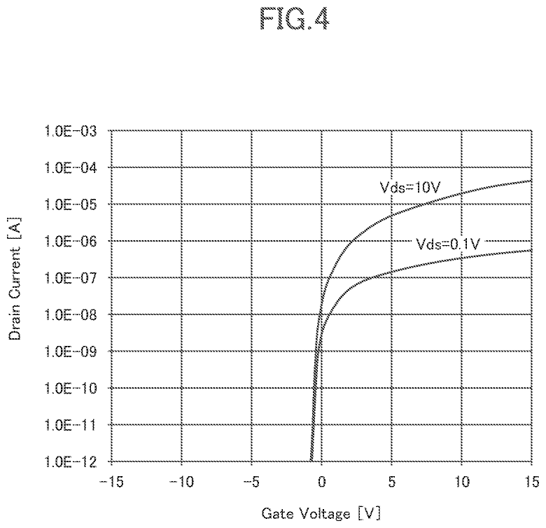

FIG. 4 is a graph showing measured drain current value with respect to the gate voltage of the transistor in a case where the oxygen diffusion-inhibiting film 18 is not formed in the above description. The graph shows two measured results of a case where the source-drain voltage Vds is 0.1 V and a case where the source-drain voltage Vds is 10 V. As the gate voltage increases beyond the switching threshold voltage, the drain current also increases.

As is clear from FIG. 4, the drain current is already generated at the point where the gate voltage is 0. In other words, it can be seen that the transistor is a so-called depletion type.

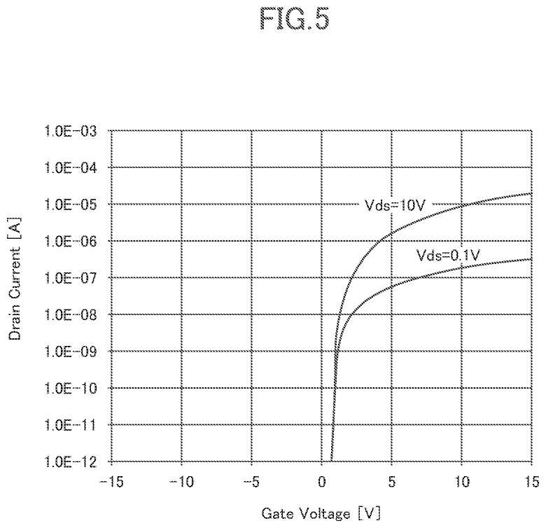

As described above, FIG. 5 is a graph showing measured values of the drain current value with respect to the gate voltage of the transistor in a case where the oxygen diffusion-inhibiting film 18 is formed. Similarly to FIG. 4, the graph shows two measured results of a case where the source-drain voltage Vds is 0.1 V and a case where the source-drain voltage Vds is 10 V.

As shown in the graph, in the case where the oxygen diffusion-inhibiting film 18 is formed, the drain current is not generated when the gate voltage is 0, and is generated only when the gate voltage becomes a positive voltage. In other words, it can be seen that the transistor is a so-called enhancement type. The example in FIG. 5 is substantially the same as the example in FIG. 4 in that the drain current increases as the gate voltage increases beyond the switching threshold voltage, and thus it can be seen that the switching threshold voltage can be shifted in the positive direction by providing the oxygen diffusion-inhibiting film 18.

As described above, the switching threshold voltage of the transistor to be manufactured can be freely shifted in the positive direction by providing or not providing the oxygen diffusion-inhibiting film 18, or by varying the size of the oxygen diffusion-inhibiting film 18 or the degree of overlap with the oxide film insulating layer 16. The threshold voltage can be easily changed by the planar shape at the time of patterning the oxygen diffusion-inhibiting film 18.

Specifically, in the case where the oxygen diffusion-inhibiting film 18 is a metal layer, the oxygen diffusion-inhibiting film can be simultaneously formed when forming the electrical connecting portion between the layers, such as the columnar structure 21 of the connection portion 20 in FIG. 3. This eliminates the need of adding a special process, and can avoid an increase in manufacturing cost and time.

Although the reason why providing the oxygen diffusion-inhibiting film 18 causes the switching threshold voltage of the transistor to shift in the positive direction is not necessarily clear, the applicant speculates that this is because, when the oxygen in the oxide semiconductor layer 13 is diffused into the upper and lower layers due to the heating during the manufacturing process of the transistor, the diffusion of oxygen is partially hindered by the oxygen diffusion-inhibiting film 18, and this serves to partially prevent the reduction in the amount of oxygen in the oxide semiconductor layer 13. On the other hand, if the entire surface of the oxide semiconductor layer 13 is covered with the oxygen diffusion-inhibiting film 18, variation in the switching threshold voltage becomes large. As such, the oxygen diffusion-inhibiting film 18 may be preferably provided in a manner to partially overlap with the oxide semiconductor layer 13.

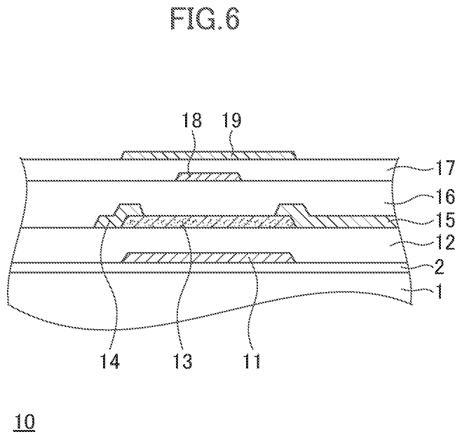

FIG. 6 is a cross-sectional view of another embodiment of the transistor 10. In FIG. 6, the position of the cross section and the display of each member are the same as those in FIG. 2, and thus the same members are denoted by the same reference numerals, and a repetitive description thereof is omitted.

As shown in FIG. 6, the oxygen diffusion-inhibiting film 18 may be formed at a position partially overlapping with a substantially central portion of the oxide semiconductor layer 13 instead of the position overlapping with the drain electrode 15. In this case as well, it is possible to freely shift the switching threshold voltage of the transistor in the positive direction.

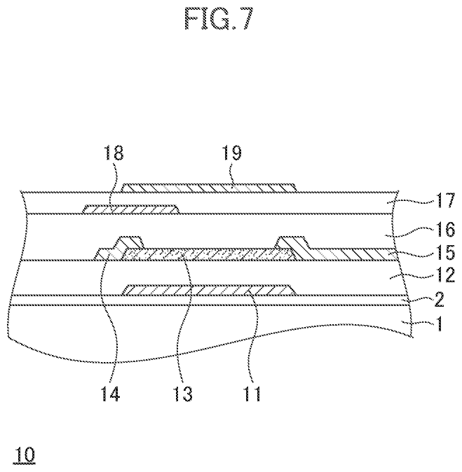

FIG. 7 is a cross-sectional view of yet another embodiment of the transistor 10. In FIG. 7 as well, the position of the cross section and the display of each member are the same as those in FIG. 2, and thus the same members are denoted by the same reference numerals, and a repetitive description thereof is omitted.

As shown in FIG. 7, the oxygen diffusion-inhibiting film 18 may be formed so as to partially overlap with the oxide semiconductor layer 13 at a position overlapping with the source electrode 14. In this case as well, it is possible to freely shift the switching threshold voltage of the transistor in the positive direction.

Further, the planar shape of the oxygen diffusion-inhibiting film 18 may have a variety of shapes, such as a shape partially having a through hole or a comb shape having a plurality of slits.

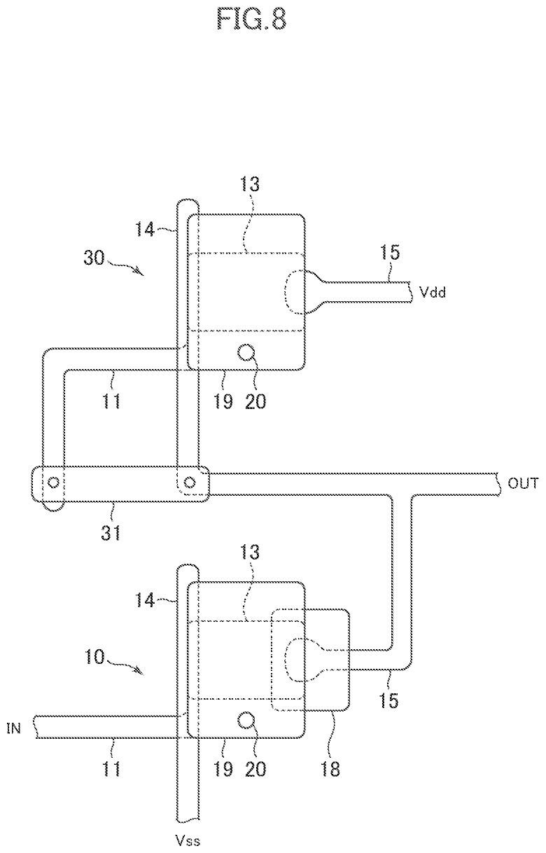

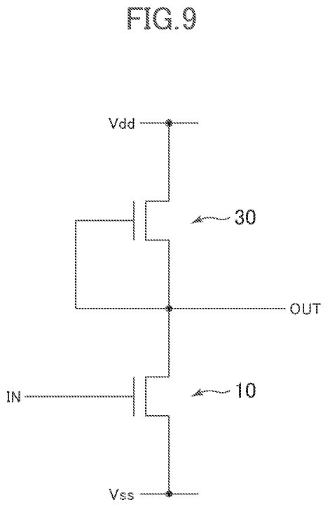

FIG. 8 is a diagram illustrating an example of an electronic circuit using the transistor 10 according to the present embodiment. The electronic circuit shown in FIG. 8 is an inverter circuit using the transistor 10 and the transistor 30 shown in a circuit diagram of FIG. 9. In the circuit, the transistors 10 and 30 using an oxide semiconductor are used. The transistor 10 is a transistor according to the present embodiment described above, and its switching threshold voltage has a positive value. The transistor 30 is a depletion type, and its switching threshold voltage is a negative value.

In the circuit, when Vdd is input to IN, the transistor 10 is turned on, and the source-drain resistance of the transistor 10 is greatly reduced. On the other hand, the source-gate voltage of the transistor 30 is 0 and the transistor 30 is a depletion type, and thus the current between the source and drain is slightly allowed. At this time, when comparing the source-drain resistance of the transistor 10 with the source-drain resistance of the transistor 30, the value of the source-drain resistance of the transistor 10 is lower, and thus Vss is output to OUT.

When inputting Vss to IN in the circuit, the transistor 10 is turned off. In this case as well, the source-gate voltage of the transistor 30 is 0 and the current between the source and drain is slightly allowed. As such, when comparing the source-drain resistance of the transistor 10 with the source-drain resistance of the transistor 30, the source-drain resistance of the transistor 30 is lower, and thus Vdd is output to OUT. In this way, the electronic circuit shown in FIG. 8 functions as an inverter circuit.

FIG. 8 shows a plan view of the transistor 10 and the transistor 30 that are simultaneously formed on the substrate. That is, the transistor 10 and the transistor 30 are formed in a simultaneous process. As such, members common to the transistor 10 and the transistor 30 are denoted by the same reference numerals and will be described together.

The lower gate electrode 11 and the upper gate electrode 19 of the transistor 10 are connected to the input IN. The source electrode 14 of the transistor 10 is connected to the negative power supply Vss. The drain electrode 15 of the transistor 10 is formed in a continuous pattern with the source electrode 14 of the transistor 30 in the same layer. Further, the drain electrode 15 of the transistor 10 and the source electrode 14 of the transistor 30 are connected to the output OUT. The lower gate electrode 11 and the upper gate electrode 19 of the transistor 30 are connected to the drain electrode 15 of the transistor 10 and the source electrode 14 of the transistor 30 via a connection electrode 31.

In both the transistor 10 and the transistor 30, the oxide semiconductor layer 13 is partially in contact with the source electrode 14 and the drain electrode 15. In this example, only in the transistor 10, the electrically floating oxygen diffusion-inhibiting film 18 is formed so as to overlap with a part of the oxide semiconductor layer 13 on the drain electrode side.

By forming the circuit in this manner, only the switching threshold voltage of the transistor 10 is shifted in the positive direction so as to generate an inverter circuit. The oxygen diffusion-inhibiting film 18 is formed at the same time as the connecting portion 20 is formed, and the connection electrode 31 is also formed at the same time. This eliminates the need of adding a special process for generating a circuit.

The inverter circuit described above is an example of an electronic circuit using the transistor 10 according to the present embodiment. Other electronic circuits may be generated using characteristics that only the switching threshold voltage can be easily shifted in the positive direction.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A thin film transistor comprising:
an active layer made of an oxide semiconductor containing at least indium and gallium;
an electrode layer partially formed on the active layer;
an oxide film insulating layer formed on the active layer and the electrode layer; and
a nitride film insulating layer formed on the oxide film insulating layer, wherein
the thin film transistor further comprises an oxygen diffusion-inhibiting film partially overlapping with the active layer in a plan view between the oxide film insulating layer and the nitride film insulating layer.

2. The thin film transistor according to claim 1, wherein
the oxygen diffusion-inhibiting film is an electrically floating metal film.

3. The thin film transistor according to claim 1, wherein
the oxygen diffusion-inhibiting film further overlaps with a drain electrode of the electrode layer.

4. The thin film transistor according to claim 1, further comprising:
a lower gate electrode disposed below the active layer through a gate insulating layer; and
an upper gate electrode connected to the lower gate electrode and formed on the nitride film insulating layer.
